(19) United States
(12) Patent Application Publication
(10) Pub. No.: US 2022/0156345 A1
(43) Pub. Date: May 19, 2022

(54) MEMORY-BASED VECTOR-MATRIX MULTIPLICATION

(71) Applicant: Adesto Technologies Corporation, Santa Clara, CA (US)

(72) Inventor: John R. Jameson, Menlo Park, CA (US)

(21) Appl. No.: 17/601,778

(22) PCT Filed: May 28, 2020
(86) PCT No.: PCT/US20/34919

§ 371 Date: Oct. 6, 2021

Related U.S. Application Data
(60) Provisional application No. 62/855,219, filed on May 31, 2019.

(51) Int. Cl. G06F 17/16; G11C 13/00

(52) U.S. Cl. CPC G06F 17/16; G11C 13/0011; G11C 13/0064; G11C 13/004; G11C 13/0028

(57) ABSTRACT

A memory device includes a memory array arranged in rows and columns; memory cell layers at each row and column intersection, where each memory cell layer is configured to be set to a predetermined conductance state; a row control circuit that is configured to apply voltages to the rows by applying sub-voltages on each row, where each sub-voltage corresponds to a different memory cell layer, and where each sub-voltage is proportional to the voltage on the corresponding row; and a sensing circuit that is configured to determine a column current flowing through a selected column in response to the application of the voltages to the rows, where the column current is a sum of currents through each memory cell layer that corresponds to the selected column.

### FIELD OF THE INVENTION

The present invention generally relates to the field of semiconductor devices. More specifically, embodiments of the present invention pertain to memory devices, including both volatile and non-volatile memory devices, such as flash memory devices, resistive random-access memory (ReRAM), and/or conductive bridging RAM (CBRAM) processes and devices.

### BACKGROUND

Non-volatile memory (NVM) is increasingly found in applications, such as solid-state hard drives, removable digital picture cards, and so on. Flash memory is the predominant NVM technology in use today. However, flash memory has limitations, such as a relatively high power, as well as relatively slow operation speed. Microprocessor performance can be very sensitive to memory latency. Many non-volatile memory devices have an access time or latency that is relatively slow as compared to the microprocessor. In addition, many implementations of various communication protocols between a microprocessor/host and memory, such as serial peripheral interface (SPI) can add even more latency than is required by the memory array itself.

### BRIEF DESCRIPTION OF THE DRAWINGS

FIG. 1 is a schematic block diagram of an example host and memory device arrangement, in accordance with embodiments of the present invention.

FIG. 2 is a schematic block diagram of an example memory device structure, in accordance with embodiments of the present invention.

FIG. 3 is a block diagram of an example memory device, in accordance with embodiments of the present invention.

FIG. 4 is a block diagram of an example memory arrangement, in accordance with embodiments of the present invention.

FIG. 5 is a block diagram of an example of memory-based vector-matrix multiplication, in accordance with embodiments of the present invention.

FIG. 6 is a block diagram of an example split-voltage memory-based vector-matrix multiplication, in accordance with embodiments of the present invention.

FIG. 7 is a block diagram of an example of split-voltage weight encoding for memory-based vector-matrix multiplication, in accordance with embodiments of the present invention.

FIG. 8 is a block diagram of an example of a 2D split-voltage approach for memory-based vector-matrix multiplication, in accordance with embodiments of the present invention.

FIG. 9 is a block diagram of an example of split-voltage weight encoding for memory-based vector-matrix multiplication, in accordance with embodiments of the present invention.

FIG. 10 is a diagram of an example of split-voltage approach for 3D integration using CBRAM memory cells, in accordance with embodiments of the present invention.

FIG. 11 is a diagram of an example of split-voltage approach for 3D integration using RRAM memory cells, in accordance with embodiments of the present invention.

FIG. 12 is a diagram of an example of verifying the weight of a single cell for memory-based vector-matrix multiplication, in accordance with embodiments of the present invention.

FIG. 13 is a flow diagram of an example method of verifying the weight of a single cell for memory-based vector-matrix multiplication, in accordance with embodiments of the present invention.

### DETAILED DESCRIPTION OF EMBODIMENTS

Reference will now be made in detail to particular embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it will be readily apparent to one skilled in the art that the present invention may be practiced without these specific details. In other instances, well-known methods, procedures, processes, components, structures, and circuits have not been described in detail so as not to unnecessarily obscure aspects of the present invention.

Some portions of the detailed descriptions which follow are presented in terms of processes, procedures, logic blocks, functional blocks, processing, schematic symbols, and/or other symbolic representations of operations on data streams, signals, or waveforms within a computer, processor, controller, device, and/or memory. These descriptions and representations are generally used by those skilled in the data processing arts to effectively convey the substance of their work to others skilled in the art. Usually, though not necessarily, quantities being manipulated take the form of electrical, magnetic, optical, or quantum signals capable of being stored, transferred, combined, compared, and otherwise manipulated in a computer or data processing system. It has proven convenient at times, principally for reasons of common usage, to refer to these signals as bits, waves, waveforms, streams, values, elements, symbols, characters, terms, numbers, or the like.

Particular embodiments may be directed to memory devices, including volatile memory, such as SRAM and DRAM, and including non-volatile memory (NVM), such as flash memory devices, and/or resistive switching memories (e.g., conductive bridging random-access memory [CBRAM], resistive RAM [ReRAM], etc.). Particular embodiments can include structures and methods of operating flash and/or resistive switching memories that can be written (programmed/erased) between one or more resistance and/or capacitive states. In one particular example, a CBRAM storage element may be configured such that when a forward or reverse bias greater than a threshold voltage is applied across electrodes of the CBRAM storage element, the electrical properties (e.g., resistance) of the CBRAM storage element can change. In any event, certain embodiments are suitable to any type of memory device, and in particular NVM devices, such as flash memory devices, and may include resistive switching memory devices in some cases.

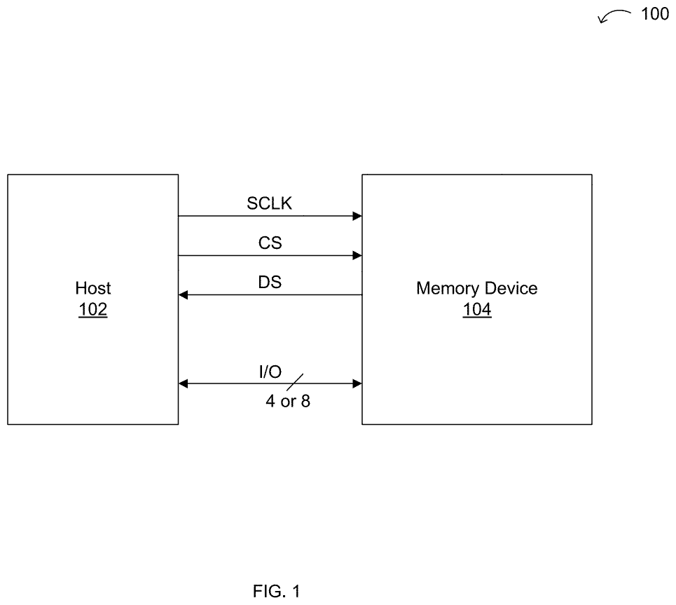

Referring now to FIG. 1, shown is an example memory device and host arrangement 100, in accordance with embodiments of the present invention. In this example, host 102 can interface with memory device 104 via a serial interface. For example, host 102 can be any suitable controller (e.g., CPU, MCU, general-purpose processor, GPU, DSP, etc.), and memory device 104 can be any type of memory device (e.g., SRAM, DRAM, EEPROM, Flash, CBRAM, magnetic RAM, ReRAM, etc.). Memory device 104 can thus be implemented in a variety of memory technologies, such as non-volatile types. In some cases, memory device 104 can be a serial flash memory that may be implemented in more traditional non-volatile memories, or in CBRAM/ReRAM resistive switching memories.

Various interface signals, such as in a serial peripheral interface (SPI), can be included for communication between host 102 and memory device 104. For example, serial clock (SCK) can provide a clock to device 104, and may be used to control the flow of data to the device. Command, address, and input data (e.g., via I/O pins) can be latched by memory device 104 on a rising edge of SCK, while output data (e.g., via I/O pins) can be clocked out of memory device 104 by SCK or data strobe (DS). Chip select (CS), which may be active low, can be utilized to select memory device 104, such as from among a plurality of such memory devices sharing a common bus or circuit board, or otherwise as a way to access the device. When the chip select signal is de-asserted (e.g., at a high level), memory device 104 can be deselected, and placed in a standby mode. Activating the chip select signal (e.g., via a high to low transition on CS) may be utilized to start an operation, and returning the chip select signal to a high state can be utilized for terminating an operation. For internally self-timed operations (e.g., a program or erase cycle), memory device 104 may not enter standby mode until completion of the particular ongoing operation if chip select is de-asserted during the operation.

In the example interface, data can be provided to (e.g., for write operations, other commands, etc.) and from (e.g., for read operations, verify operations, etc.) memory device 104 via the I/O signals. For example, input data on the I/O can be latched by memory device 104 on edges of SCK, and such input data can be ignored if the device is deselected (e.g., when the chip select signal is de-asserted). Data can be output from memory device 104 via the I/O signals as well. For example, data output from memory device 104 can be clocked out on edges of DS or SCK for timing consistency, and the output signal can be in a high impedance state when the device is deselected (e.g., when the chip select signal is de-asserted).

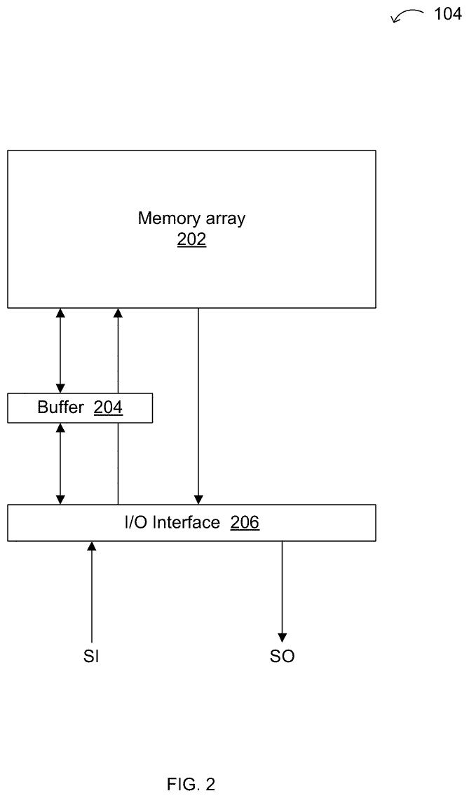

Referring now to FIG. 2, shown is a schematic block diagram of an example memory device 104 structure, in accordance with embodiments of the present invention. For example, memory device 104 can include memory array 202, buffer 204 (e.g., SRAM or other fast access memory), and I/O interface 206. In some arrangements, more than one buffer 204 can be provided, such as a buffer for an input path, and another buffer for an output path. Alternatively, or in addition, multiple buffers can be provided for multi-layer buffering. For example, memory device 104 can be configured as a data flash and/or a serial flash device. Memory array 202 can be organized as any suitable number of pages of data. For example, each page can include 256 or 264 bytes of data. Similarly, buffer 204 can store at least a page of data. I/O interface 206 can provide interfacing between memory array 202, buffer 204, and serial data input (SI) and output (SO). For example, I/O interface 206 may be part of an SPI or other serial type of interface, and may also support a number of SPI interface modes (e.g., Single SPI, QPI, and Octal modes).

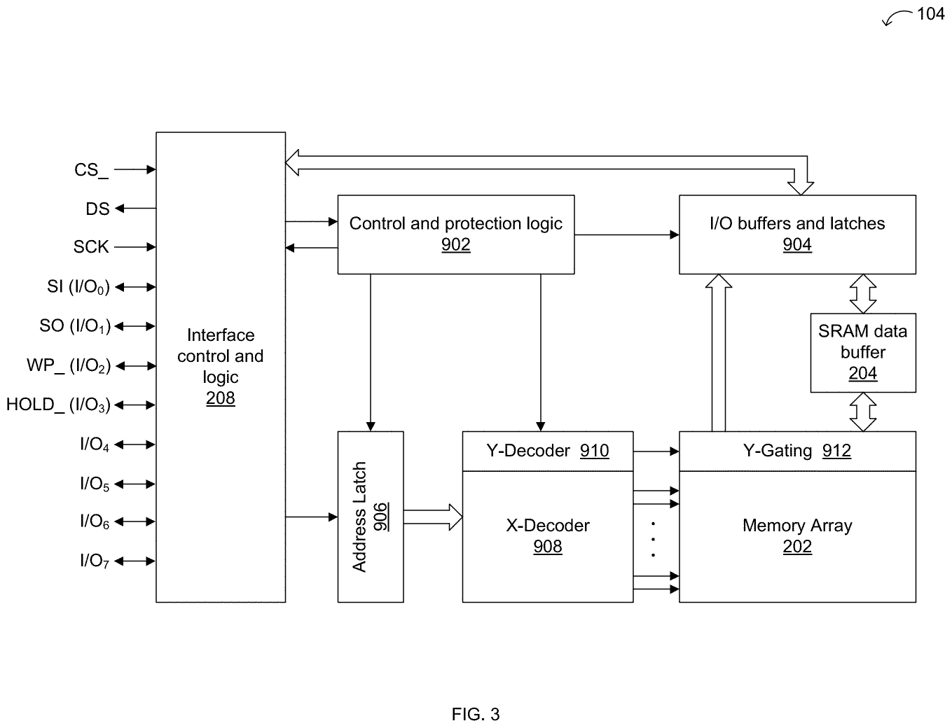

Referring now to FIG. 3, shown is a block diagram of an example memory device, in accordance with embodiments of the present invention. Memory device 104 can include interface control and logic 208, which may manage the interface (e.g., SPI interface), and decode the command and address information. Control and protection logic 902 can include control circuitry for reading and writing to the memory array, including address mapping and control for byte access and group addressing/ordering, as will be discussed in more detail below. For example, control and protection logic 902 can include a command decoder, registers for command execution parameters (e.g., read parameters, program/erase parameters, etc.), as well as a controller for command execution.

I/O buffers and latches 904 can control the input of data from interface control and logic 208, and the output of data to interface control and logic 208. For example, chip select based control and clock based control of data read from memory array 202 can be accommodated via I/O buffers and latches 904. That is, registers/latches in I/O buffers and latches 904 can be controlled by way of the toggling of SCK during burst reads and sequential fetch operations, as described herein. SRAM data buffer(s) 204 can buffer/store data between memory array 202 and I/O buffers and latches 904. Address latch block 906 can receive address information via interface control and logic 208, and may provide latched addresses to X-decoder 908 for row addresses, and to Y-decoder 910 for column addresses. Incrementing of addresses can be performed via address latch block 906 and/or control and protection logic 902. Y-decoder 910 can provide column addresses to Y-Gating 912, which can include pass gates or the like to multiplex I/O lines to/from memory array 202. As discussed above, memory array 202 can include an array of volatile memory cells, or non-volatile memory cells (e.g., CBRAM, ReRAM, Flash, etc.).

In one embodiment, a memory device can include: a memory array arranged in a plurality of rows and a plurality of columns; a plurality of memory cell layers at each row and column intersection, where each memory cell layer is configured to be set to a predetermined conductance state such that the plurality of memory cell layers corresponds to a plurality of predetermined conductance states; a row control circuit configured to apply a plurality of voltages to the plurality of rows by applying a plurality of sub-voltages on each row of the plurality of rows, where each sub-voltage of the plurality of sub-voltages corresponds to a different one of the plurality of memory cell layers, and where each sub-voltage is proportional to the voltage of the plurality of voltages on the corresponding row; and a sensing circuit configured to determine a column current flowing through a selected column of the plurality of columns in response to the application of the plurality of voltages to the plurality of rows, where the column current is a sum of currents through each memory cell layer that corresponds to the selected column.

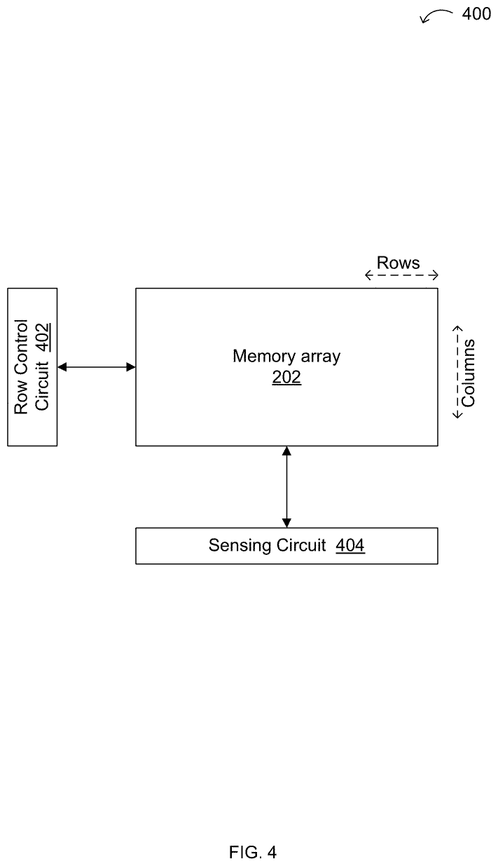

Referring now to FIG. 4, shown is a schematic block diagram of an example memory arrangement 400, in accordance with embodiments of the present invention. For example, memory array 202 can be arranged in rows and columns, and can include any number of sub-arrays, as well as other supporting circuitry. Row control circuit 402 can apply voltage levels on the rows, such as for accessing memory cells, setting conductance values on the various memory cell layers, and so on. In addition, sensing circuit 404 can be used to read the memory cells, including for memory cell conductance value verification, and in particular may be used in order to determine current flowing on column lines. For example, the current as read may correspond to various memory cell layer conductance values, as based on the word line/row voltage levels applied to the various memory cell layers therein.

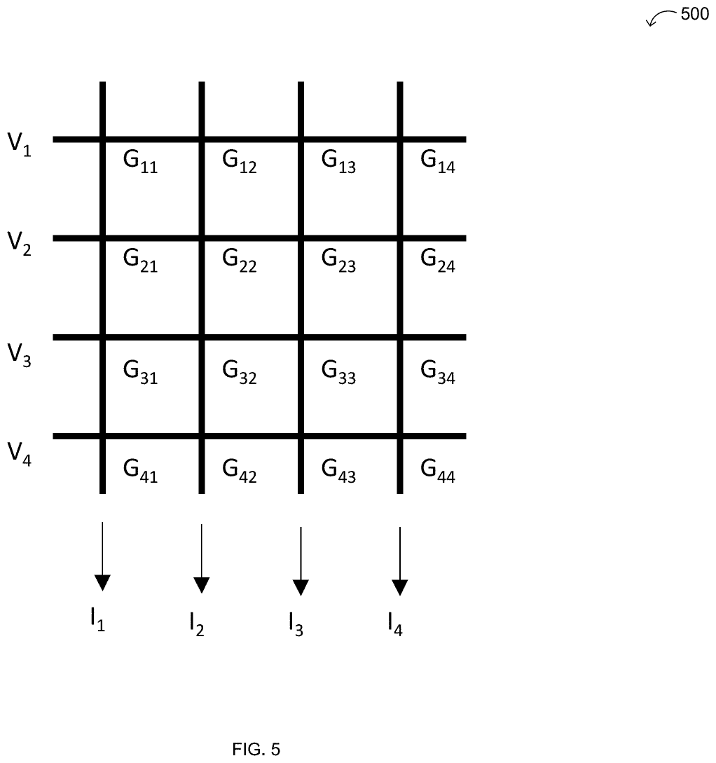

Referring now to FIG. 5, shown is a block diagram of an example of memory-based vector-matrix multiplication, in accordance with embodiments of the present invention. A 2D memory array 500 can be formed, including rows and columns of conductive lines. One or more memory devices is formed at each node. In particular embodiments, a memory device/memory cell can include a nonvolatile memory cell, such as a resistive RAM (RRAM) cell, conductive bridging memory (CBRAM) cell, magnetic RAM (MRAM) cell, spin transfer torque MRAM (STT-MRAM) cell, phase change memory (PCM) cell, flash memory cell, floating gate flash cell, split-gate flash cell, SONOS cell, MNOS cell, ferroelectric RAM (FRAM) cell, as to name but a few. In particular embodiments, a memory device can also include an access device (e.g., a transistor, a bipolar transistor, a field-effect transistor, a diode, a thin film diode, a Schottky diode, a bipolar diode, an Ovonic threshold switch, a semiconductor diode, a silicon diode, etc.).

One or more memory devices or memory cell layers at node ij may be configured to provide a path of conductance Gᵢⱼ between row i and column j. For example, input voltages Vᵢ may be applied to the rows (e.g., by row control circuit 402). The currents through all nodes on a given column j may be added up, thus yielding a total current Iⱼ (e.g., can be sensed via sensing circuit 404). For example, the current in the first (j=1) column in FIG. 5 to the left is I₁=V₁G₁₁+V₂G₂₁+V₃G₃₁+V₄G₄₁. In this way, the vector-matrix multiplication VG=I can be achieved, and the numerical values of the Vᵢ, Gᵢⱼ, and Iⱼ can be mapped to the variables in a particular problem of interest. As but one example, vector-matrix multiplication is common in machine learning algorithms such as neural networks, deep neural networks, convolutional networks, etc. Such algorithms are used for tasks such as image identification, natural language processing (e.g., translation), signal classification, etc. In this context, e.g., the conductances Gᵢⱼ in FIG. 5 may correspond to the “weights” of a layer of a network, and the voltages Vᵢ and currents Iⱼ may correspond to inputs and outputs to that layer, respectively. As may be familiar to one skilled in the art, the outputs of one layer of such a network may serve as inputs to a next layer of a network. Additional operations (e.g., an activation function) may also be applied to the outputs of a layer so as to produce a set of modified outputs which may serve as inputs to a next layer of a network. Other applications which may utilize vector-matrix multiplication include such things as minimization, numerical solution of differential equations, and spectrum analysis (e.g., Fourier analysis), to name but a few.

The input Vᵢ can generally be continuous (e.g., analog) variables, and it is desirable for many problems of interest that the conductances Gᵢⱼ also be continuous variables, in order to allow any vector V and matrix G to be used and to make the multiplication as accurate as possible. For a given input vector V, any inaccuracy or unintended change in the value of one or more of the conductances Gᵢⱼ can cause inaccuracy in one or more output currents Iⱼ. Thus, a general case of memory-based vector-matrix multiplication may call for memory cells having conductances that: (i) can be set to a high number of different conductance values in a controllable manner; and (ii) do not change values after being set. This can be difficult to meet with existing memory technologies, and becomes increasingly difficult to meet as most memory technologies are scaled to smaller nodes. Therefore, a challenge for memory-based vector-matrix multiplication is to maximize the numerical accuracy of the computation, while also minimizing the number of stable and repeatable conductance levels that the memory cells are to achieve.

In particular embodiments, a “split-voltage” approach to memory-based vector-multiplication is disclosed. Numerical accuracy can be judged by how well the currents Iⱼ which flow down the j columns match their intended values. Although the current on a given column can be written as a sum of VᵢGᵢⱼ products (e.g., I₁=V₁G₁₁+V₂G₂₁+V₃G₃₁+V₄G₄₁), the individual terms (e.g., V₂G₂₁) themselves may be of less concern as standalone values. Instead, the sum of the individual products can be of the greater concern, and as such the accuracy and repeatability may be determined primarily based on maintaining this summation of VᵢGᵢⱼ products as unchanged. In the “sub-voltage” approach of certain embodiments, a third “dimension” or layer, k, is introduced, such that each VᵢGᵢⱼ product may be written as a sum VᵢGᵢⱼ=ΣₖVₖᵢGₖᵢⱼ, where Σₖ represents a sum over the k-component. The current Iⱼ originally flowing down column j can accordingly be a sum of the k “sub-currents” Iₖⱼ, i.e., Iⱼ=ΣₖIₖⱼ=ΣₖΣᵢVₖᵢGₖᵢⱼ. This may provide an additional degree of freedom that allows limitations on the physical conductances that are achievable by a memory cell to be accommodated by suitable choices of the “sub-voltages” Vᵢₖ and number of layers k.

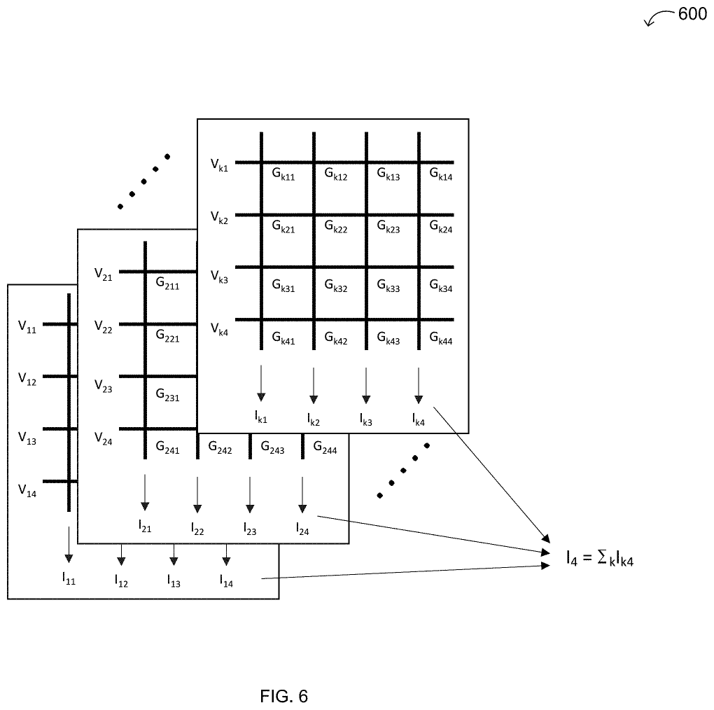

Referring now to FIG. 6, shown is a block diagram of an example split-voltage memory-based vector-matrix multiplication, in accordance with embodiments of the present invention. In example 600, current I₄ that would flow down the 4^{th} column of the 2D array would accordingly be obtained by summing the currents flowing down the 4^{th} column of the k different layers (e.g., I₄=ΣₖIₖ₄). In this way, the previous 2D system may effectively be expanded into a 3^{rd} dimension as shown. Of course, any number of k different layers, as well as memory cell layer arrangements and an array/sub-array sizes can be accommodated in certain embodiments.

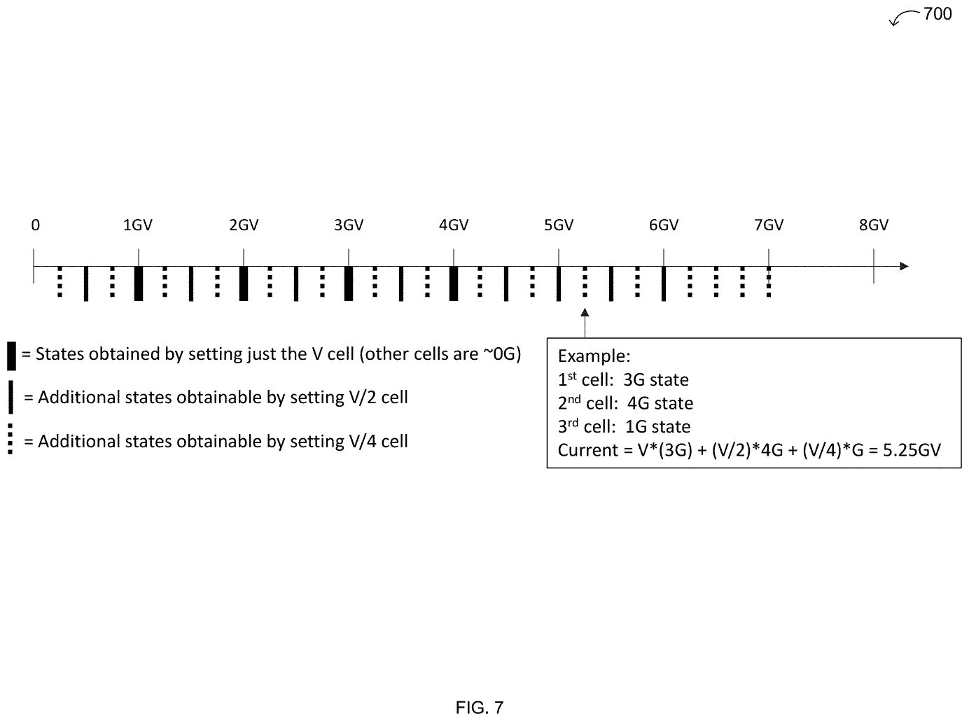

Referring now to FIG. 7, shown is a block diagram of an example of split-voltage weight encoding for memory-based vector-matrix multiplication, in accordance with embodiments of the present invention. In particular example 700, a single memory cell can effectively be programmed to 4 evenly spaced conductance states having values G, 2 G, 3 G, 4 G, such that G=50 uS, and which respectively corresponds to resistances of 5, 10, 6.7, and 20 kΩ. For example, three memory cells can be used per weight, with sub-voltages of V (e.g., the original input voltage), V/2, and V/4. Accordingly, a total current (e.g., sum of the 3 cells) from 0 to 7 GV in increments of GV/4 is achievable, as shown. The total number of accessible current levels in this example is 28 (excluding 0 GV), or about 4.8 unsigned bits equivalent. By adding a 4^{th} cell at voltage V, the number of accessible levels can be increased to 44, or log₂(44)=5.5 bits equivalent. Further, the use of negative voltages can double the number of accessible current levels, or log₂(88), which is about 6.5 bits equivalent. The theoretical maximum from 4 cells with 4 levels each in this example would be log₂(4⁴)=8 bits equivalent. As shown in this particular example, 1^{st} cell: 3 G state, 2^{nd} cell: 4 G state, 3^{rd} cell: 1 G state, and Current=V*(3 G)+(V/2)*4 G+(V/4)*G=5.25 GV.

In particular embodiments, a much higher number of states than in other approaches are achievable with different split-voltage schemes. The split-voltage concept as described herein can allow the multi-level capability of a memory cell to be fully utilized, without requiring such memory cells to provide relatively small changes in conductance, or relatively large currents. In addition, this approach allows for improved resolution near 0 current. Many choices of sub-voltages and numbers of cells are possible in certain embodiments. Table 1 below shows the number of current levels accessible (excluding 0 GV) for various different choices of sub-voltages, whereby the conductance states of a cell are assumed to be equally spaced in increments of “G”, and the input voltage is assumed to be positive (i.e., V>=0) in this example.

TABLE 1

| | # of con- | | Spacing | | | | | # of |
|---|---|---|---|---|---|---|---|---|
| | ductance | | between | | | | | bits |
| # of | states per | Sub- | current | | Maximum | | # | equiv- |
| cells | cell | voltages | levels | | current | | States | alent |
| 2 | 4 | V, V/3 | 0.33 | GV | 5.33 | GV | 16 | 4.0 |
| 3 | 4 | V, V/3, V/9 | 0.11 | GV | 5.8 | GV | 52 | 5.7 |
| 2 | 5 | V, V/3 | 0.33 | GV | 6.7 | GV | 20 | 4.3 |
| 3 | 5 | V, V/3, V/9 | 0.11 | GV | 7.2 | GV | 65 | 6.0 |
| 2 | 6 | V, V/3 | 0.33 | GV | 8.0 | GV | 24 | 4.6 |
| 3 | 6 | V, V/3, V/9 | 0.11 | GV | 8.7 | GV | 78 | 6.3 |

In particular embodiments, a number of different column currents is equal to

$$1 + {N}_{G} ( {\sum }_{i}^{{N}_{V}} \frac{V}{{k}_{i}} ) max ( {k}_{i} ) ,$$

where N_{G} is the number of predetermined conductance states, N_{V} is the number of memory cell layers, and V/kᵢ is the sub-voltage applied to memory cell layer i. The 1 may be included in order to represent the case where all cells are in an off state and the current is approximately 0 (Table 1 does not include this 0-current state). This example formula above assumes all the sub-voltages are the same sign. For the case where any given sub-voltages could be positive or negative, a 2 may be added in front of the N_{G}, i.e.,

$$1 + 2 {N}_{G} ( {\sum }_{i}^{{N}_{V}} \frac{V}{{k}_{i}} ) max ( {k}_{i} ) .$$

Further, a bit equivalent to the number of different column currents may be equal to the binary logarithm of

$$1 + {N}_{G} ( {\sum }_{i}^{{N}_{V}} \frac{V}{{k}_{i}} ) max ( {k}_{i} )$$

when the sub-voltages are the same sign, or the binary logarithm of

$$1 + 2 {N}_{G} ( {\sum }_{i}^{{N}_{V}} \frac{V}{{k}_{i}} ) max ( {k}_{i} )$$

when the sub-voltages could be positive or negative.

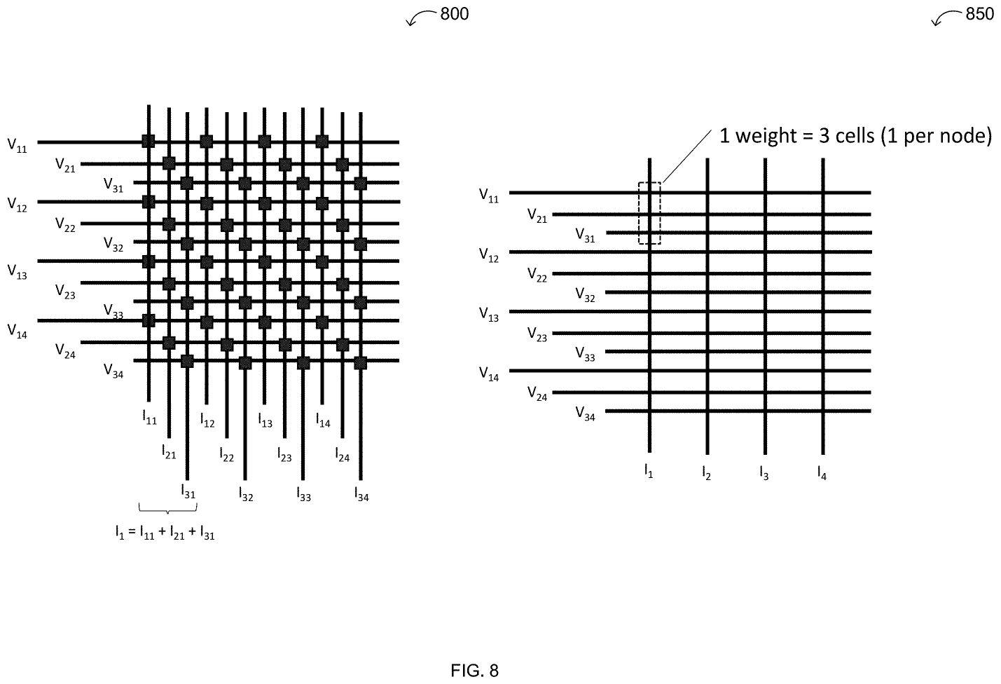

Referring now to FIG. 8, shown is a block diagram of an example of a 2D split-voltage approach for memory-based vector-matrix multiplication, in accordance with embodiments of the present invention. The k layers of the sub-voltage approach can effectively be flattened in order to allow the approach to be implemented in a 2D physical array. In example 800, black squares may depict memory devices connecting (or otherwise coupled to) the horizontal and vertical lines which intersect at that location. Nodes not having squares are not connected, and are instead “opens” in this arrangement. In example 850, all nodes can contain memory devices/cells. In particular embodiments, a memory device can include an access device (e.g., a transistor, a bipolar transistor, a field-effect transistor, a diode, a thin film diode, a Schottky diode, a bipolar diode, an Ovonic threshold switch, a semiconductor diode, a silicon diode, etc.). Unlike the array as shown in example 800, the sub-voltages may utilize a common vertical line in particular example 850.

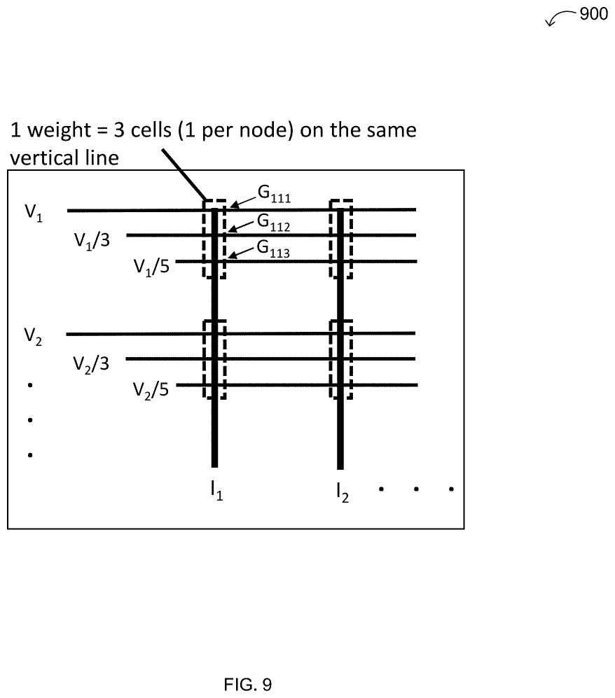

Referring now to FIG. 9, shown is a block diagram of an example of split-voltage weight encoding for memory-based vector-matrix multiplication, in accordance with embodiments of the present invention. In order to reduce the demand that the conductance of a memory device be changeable in very small increments, a “split-voltage” approach can be utilized for weight encoding. In example 900, a given input Vᵢ can be “split” into k “sub-voltages” Vᵢₖ, which can be proportional to Vᵢ but generally not equal. In FIG. 9, these sub-voltages are Vᵢ, Vᵢ/3, and Vᵢ/5. In particular embodiments, a separate memory cell layer may be assigned to each such sub-voltage. In the example to the left, a cell whose weight was originally G₁₁ can now be represented by three memory devices/cells having “sub-weights” G₁₁₁, G₁₁₂, and G₁₁₃. The sub-weights can be chosen such that the sum of their currents matches as closely as possible to the current that would have originally been produced by this node (e.g., V₁G₁₁=V₁G₁₁₁+(V₁/3)G₁₁₂+(V₁/5)G₁₁₃).

In one embodiment, a method of controlling a memory device having a memory array arranged in a plurality of rows and a plurality of columns, and a plurality of memory cell layers at each row and column intersection, can include: setting each memory cell layer to a predetermined conductance state such that the plurality of memory cell layers corresponds to a plurality of predetermined conductance states; applying a plurality of voltages to the plurality of rows by applying a plurality of sub-voltages on each row of the plurality of rows, where each sub-voltage of the plurality of sub-voltages corresponds to a different one of the plurality of memory cell layers, and where each sub-voltage is proportional to the voltage of the plurality of voltages on the corresponding row; and determining a column current flowing through a selected column of the plurality of columns in response to the application of the plurality of voltages to the plurality of rows, where the column current is a sum of currents through each memory cell layer that corresponds to the selected column.

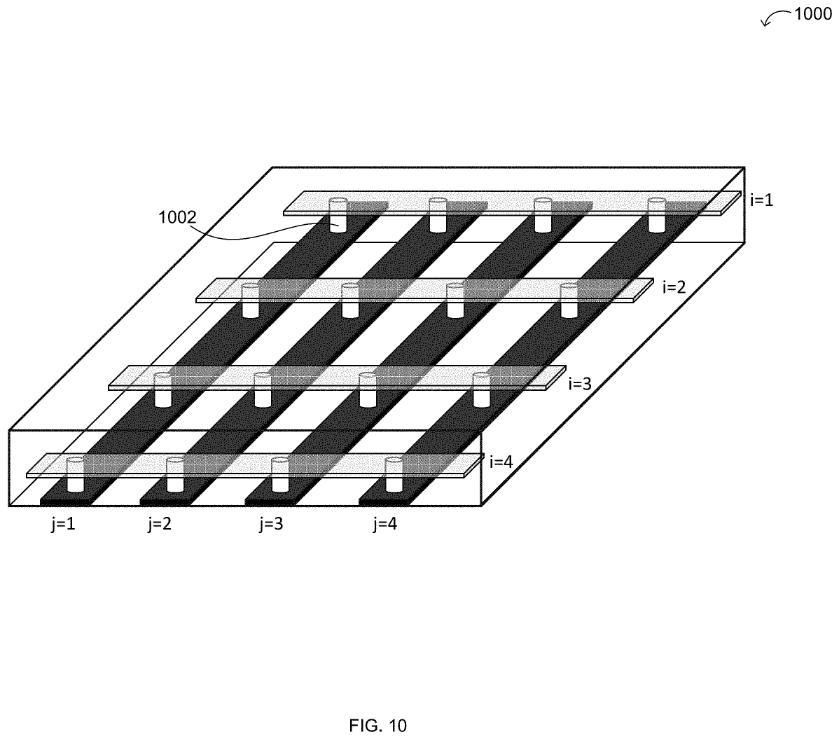

Referring now to FIG. 10, shown is a diagram of an example of split-voltage approach for 3D integration using CBRAM memory cells, in accordance with embodiments of the present invention. A portion of a single layer is shown here in example 1000. This CBRAM memory cell array can include columns (j) and rows (i), with 4 of each shown in this example. Each node can include a via 1002 that serves as the cathode of a particular CBRAM cell. The rows may serve as the switching layer and anode of the memory devices/cells. For example, the columns can include Cu, the vias might can include a metal (e.g., Ta or TaₓSi_{y}), and the rows can be multi-layer stacks including sub-layers having an oxide (e.g., SiO₂), an anode (e.g., HfₓTe_{y}), a capping layer (e.g., TaₓSi_{y}), and an optional strapping layer (e.g., a metal) to reduce the resistance of the line. Each node of such an array may also include a 2-terminal access device positioned at each node and in series with the CBRAM cell.

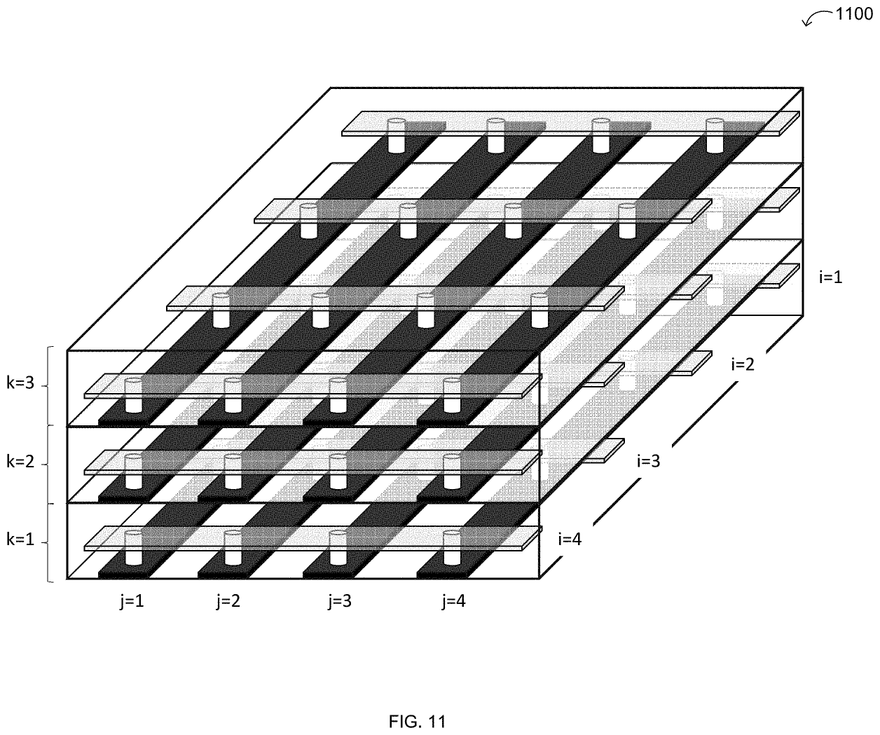

Referring now to FIG. 11, shown is a diagram of an example of split-voltage approach for 3D integration using RRAM memory cells, in accordance with embodiments of the present invention. This example 1100 shows a 3D integration including multiple layers of memory cells. Of course, any suitable number of layers of memory cells, as well as rows and columns in the memory array, can be supported in certain embodiments.

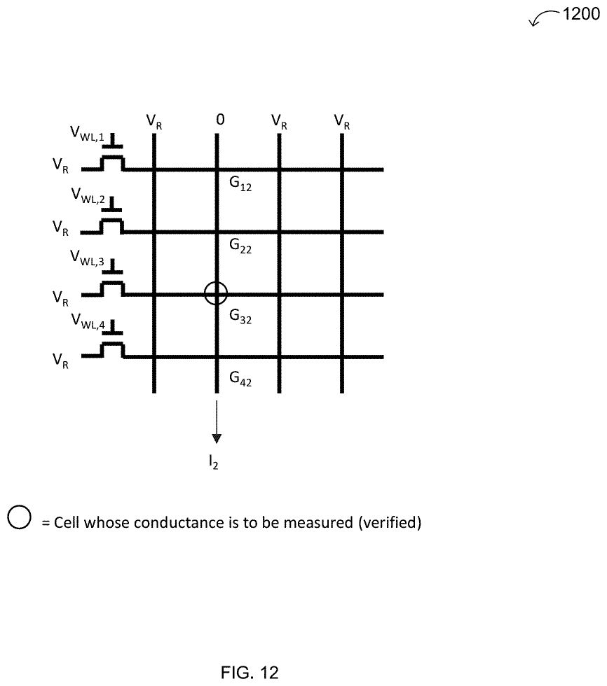

Referring now to FIG. 12, shown is a diagram of an example of verifying the weight of a single cell for memory-based vector-matrix multiplication, in accordance with embodiments of the present invention. In example 1200, all rows and columns can be brought to a read voltage, VR (e.g., 0.2V). The voltage can be dropped to 0 on the column containing the cell to be verified (e.g., j=2). The current Iⱼ flowing out of the column (e.g., I₂) can then be measured. The voltage applied to the row containing the cell to be verified (e.g., i=3) can be changed from V_{R} to V_{R}′ (e.g., V_{R}′=0.4V). The current Iⱼ′ flowing out the column (e.g., I₂′) can be measured. The conductance of the cell to be verified can be determined as G=(Iᵢ′−Iᵢ)/(V_{R}′−V_{R}). In this way, the weight of a single memory cell can be verified for memory-based vector-matrix multiplication.

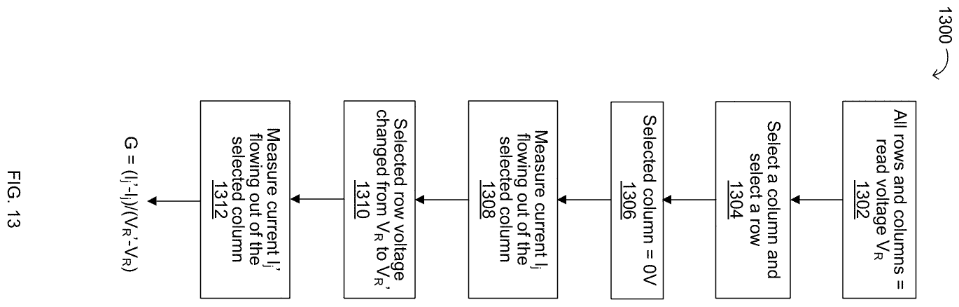

Referring now to FIG. 13, shown is a flow diagram of an example method of verifying the weight of a single cell for memory-based vector-matrix multiplication, in accordance with embodiments of the present invention. In example 1300, all rows and columns can be brought to a read voltage V_{R} at 1302. At 1304, a column and a row can be selected (e.g., the row/column that contains the cell to be verified). At 1306, the voltage can be dropped to 0V on the selected column. At 1308, the current Iⱼ flowing out of the selected column can be measured. At 1310, the voltage applied to the selected row can be changed from V_{R} to V_{R}′. At 1312, the current flowing out the selected column can be measured, and the conductance of the cell to be verified can be determined as G=(Iᵢ′−Iᵢ)/(V_{R}′−V_{R}).

While the above examples include circuit, operational, and structural implementations of certain memory cells and programmable impedance devices, one skilled in the art will recognize that other technologies and/or cell structures can be used in accordance with embodiments. Further, one skilled in the art will recognize that other device circuit arrangements, architectures, elements, and the like, may also be used in accordance with embodiments. Further, the resistance levels, operating conditions, and the like, may be dependent on the retention, endurance, switching speed, and variation requirements of a programmable impedance element.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

1. A memory device, comprising:
a) a memory array arranged in a plurality of rows and a plurality of columns;
b) a plurality of memory cell layers at each row and column intersection, wherein each memory cell layer is configured to be set to a predetermined conductance state such that the plurality of memory cell layers corresponds to a plurality of predetermined conductance states;
c) a row control circuit configured to apply a plurality of voltages to the plurality of rows by applying a plurality of sub-voltages on each row of the plurality of rows, wherein each sub-voltage of the plurality of sub-voltages corresponds to a different one of the plurality of memory cell layers, and wherein each sub-voltage is proportional to the voltage of the plurality of voltages on the corresponding row; and
d) a sensing circuit configured to determine a column current flowing through a selected column of the plurality of columns in response to the application of the plurality of voltages to the plurality of rows, wherein the column current is a sum of currents through each memory cell layer that corresponds to the selected column.

2. The memory device of claim 1, wherein the plurality of predetermined conductance states are equally spaced apart conductance states.

3. The memory device of claim 2, wherein a remaining each of the plurality of predetermined conductance states are multiples of a first predetermined conductance state.

4. The memory device of claim 1, wherein each sub-voltage is a ratio of the voltage of the plurality of voltages on the corresponding row.

5. The memory device of claim 1, wherein a number of different column currents is equal to
$$1 + {N}_{G} ( {\sum }_{i}^{{N}_{V}} \frac{V}{{k}_{i}} ) max ( {k}_{i} ) ,$$
wherein N_{G} is the number of predetermined conductance states, N_{V} is the number of memory cell layers, and V/kᵢ is the sub-voltage applied to memory cell layer i.

6. The memory device of claim 5, wherein a bit equivalent to the number of different column currents is equal to the binary logarithm of
$$1 + {N}_{G} ( {\sum }_{i}^{{N}_{V}} \frac{V}{{k}_{i}} ) max ( {k}_{i} ) .$$

7. The memory device of claim 1, wherein each of the memory cell layers comprises conductive bridging random-access memory (CBRAM) whereby each of the plurality of rows serve as an anode of CBRAM cells.

8. The memory device of claim 7, wherein:
a) each of the plurality of columns comprises a metal;
b) a plurality of vias comprises a metal; and
c) each of the plurality of rows comprises a multi-layer stack having an oxide, an anode, and a capping layer.

9. The memory device of claim 1, wherein each of the memory cell layers comprises resistive RAM (ReRAM).

10. The memory device of claim 1, wherein each of the plurality of predetermined conductance states is verified by the row control circuit and the sensing circuit being configured to:
a) raise each of the plurality of rows and the plurality of columns to a predetermined read voltage;
b) measure a current flowing out of a selected of the plurality of columns;
c) change the voltage applied to the row containing the cell to be verified to a verification voltage; and
d) measure a current flowing out of the selected column in order to verify a desired conductance state.

11. A method of controlling a memory device having a memory array arranged in a plurality of rows and a plurality of columns, and a plurality of memory cell layers at each row and column intersection, the method comprising:
a) setting each memory cell layer to a predetermined conductance state such that the plurality of memory cell layers corresponds to a plurality of predetermined conductance states;
b) applying a plurality of voltages to the plurality of rows by applying a plurality of sub-voltages on each row of the plurality of rows, wherein each sub-voltage of the plurality of sub-voltages corresponds to a different one of the plurality of memory cell layers, and wherein each sub-voltage is proportional to the voltage of the plurality of voltages on the corresponding row; and
c) determining a column current flowing through a selected column of the plurality of columns in response to the application of the plurality of voltages to the plurality of rows, wherein the column current is a sum of currents through each memory cell layer that corresponds to the selected column.

12. The method of claim 11, wherein the plurality of predetermined conductance states are equally spaced apart conductance states.

13. The method of claim 12, wherein a remaining each of the plurality of predetermined conductance states are multiples of a first predetermined conductance state.

14. The method of claim 11, wherein each sub-voltage is a ratio of the voltage of the plurality of voltages on the corresponding row.

15. The method of claim 11, wherein a number of different column currents is equal to
$$1 + {N}_{G} ( {\sum }_{i}^{{N}_{V}} \frac{V}{{k}_{i}} ) max ( {k}_{i} ) ,$$
wherein N_{G} is the number of predetermined conductance states, N_{V} is the number of memory cell layers, and V/kᵢ is the sub-voltage applied to memory cell layer i.

16. The method of claim 15, wherein a bit equivalent to the number of different column currents is equal to the binary logarithm of
$$1 + {N}_{G} ( {\sum }_{i}^{{N}_{V}} \frac{V}{{k}_{i}} ) max ( {k}_{i} ) .$$

17. The method of claim 11, wherein each of the memory cell layers comprises conductive bridging random-access memory (CBRAM) whereby each of the plurality of rows serve as an anode of CBRAM cells.

18. The method of claim 17, wherein:
a) each of the plurality of columns comprises a metal;
b) a plurality of vias comprises a metal; and
c) each of the plurality of rows comprises a multi-layer stack having an oxide, an anode, and a capping layer.

19. The method of claim 11, wherein each of the memory cell layers comprises resistive RAM (ReRAM).

20. The method of claim 11, further comprising verifying each of the plurality of predetermined conductance states by:
a) raising each of the plurality of rows and the plurality of columns to a predetermined read voltage;
b) measuring a current flowing out of a selected of the plurality of columns;
c) changing the voltage applied to the row containing the cell to be verified to a verification voltage; and
d) measuring a current flowing out of the selected column in order to verify a desired conductance state.
